(19) United States
(12) Patent Application Publication
(10) Pub. No.: US 2024/0381628 A1
(43) Pub. Date: Nov. 14, 2024

(54) MEMORY DEVICES WITH INTEGRATED FDSOI TRANSISTOR

(71) Applicant: Micron Technology, Inc., Boise, ID (US)

(72) Inventors: Srinivas Pulugurtha, Boise, ID (US); Anthony J. Kanago, Boise, ID (US)

(21) Appl. No.: 18/659,367

(22) Filed: May 9, 2024

Related U.S. Application Data
(60) Provisional application No. 63/465,409, filed on May 10, 2023.

(51) Int. Cl. H10B 12/00

(52) U.S. Cl. CPC H10B 12/50; H10B 12/09; H10B 12/315; H10B 12/482

(57) ABSTRACT

A variety of applications can include a memory device having a memory array region on a memory die and a periphery to the memory array region on the memory die, where the periphery can include a fully depleted silicon-on-insulator (FDSOI) complementary metal-oxide-semiconductor (CMOS) device. A metal shield can be integrated in the memory array region, where the metal shield is structured as a shield to digit lines of the memory array. A metal body plate in the periphery can be structured as a back gate to the FDSOI CMOS device.

### PRIORITY APPLICATION

This application claims the benefit of priority to U.S. Provisional Application Ser. No. 63/465,409, filed May 10, 2023, which is incorporated herein by reference in its entirety.

### FIELD OF THE DISCLOSURE

Embodiments of the disclosure relate generally to integrated circuits, and more specifically, to memory devices integrating a fully depleted silicon-on-insulator transistor and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, transistors in an integrated circuit for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates an example stack of material processed to support the integration of a process flow to form a memory device having a fully depleted silicon-on-insulator complementary metal-oxide-semiconductor device in a periphery to a memory array, in accordance with various embodiments.

FIGS. 2-5 show different cross-sectional views of an example memory device, where the views include views of a memory array region and views of a periphery to the memory array region, in accordance with various embodiments.

FIG. 6 shows an example substrate structure that is an engineered substrate that can be used to fabricate a memory device having the memory array regions and peripheries of or similar to FIGS. 2-5, in accordance with various embodiments.

FIGS. 7-10 illustrate an example process flow of an integrated periphery and memory array region for a memory die, in which the periphery includes one or more fully depleted silicon-on-insulator transistors, in accordance with various embodiments.

FIG. 11 is a flow diagram of features of an example method of forming a memory device, in accordance with various embodiments.

FIG. 12 is a flow diagram of features of an example method of forming a dynamic random-access memory device, in accordance with various embodiments.

FIG. 13 is a schematic of an example dynamic random-access memory device that can include an architecture having a memory array region and periphery region to the memory array, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

To implement a DRAM with a 4F² memory array configuration, metal digit lines (DLs) would typically be used. Memory cell sizes are measured using an nF² formula where ‘n’ is a constant derived from the cell design and ‘F’ is the feature size of the process technology. For the same feature size, as the cell size becomes smaller, memory capacity increases. In a 4F² memory cell, the access line pitch and the digit line pitch equal 2F. To fabricate metal digit lines, a backside processing of a wafer would be used to enable production of the metal DLs. However, metal lines in a backside processing places barriers on integration of conventional complementary metal-oxide-semiconductor (CMOS) devices in the circuits of the periphery to the 4F² memory array configuration.

In various embodiments, a fully depleted silicon-on-insulator (FDSOI) CMOS device can be integrated with 4F² memory array of a DRAM. A FDSOI transistor includes an undoped thin semiconductor channel on a buried oxide between a doped source and a doped drain. In forming the FDSOI CMOS device integrated with a memory array, a process flow combining backside processing and frontside processing can be performed that integrates SOI CMOS technology and also ensures an exceptionally clean interface quality for CMOS devices in the periphery to the memory array. Without these production features, wafer thinning processes involved in wafer-to-wafer (W2 W) technologies can result in relatively high CMOS device leakage. A FDSOI CMOS device integrated with 4F² memory array of a DRAM can provide for higher device performance, improved CMOS scalability, and improved device variability due to reduced random dopant fluctuation (RDF). RDF is the unintentional random variation of dopant atoms inside a semiconductor. RDF is typically high for devices that have higher doping. A thin silicon channel of an integrated FDSOI CMOS device can help control charge leakage without use of significant amount of dopant atoms. The device performance, in terms of switching speed versus leakage, can be improved due to multiple reasons. Such reasons can include increased electron mobility or hole mobility due to less dopants in channel, much better gate control that improves transconductance and sub-threshold slope, and improved short channel effects. FDSOI CMOS integration can also contribute to scaling down memory device dimensions without losing performance.

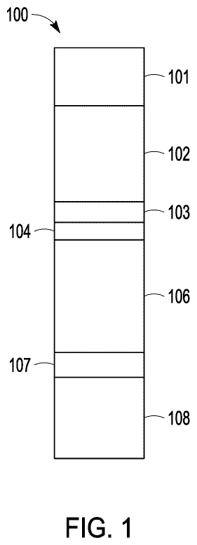

FIG. 1 illustrates an embodiment of an example stack 100 of material processed to support the integration of a process flow to form a memory device having a FDSOI CMOS device in a periphery to a memory array. The periphery can be integrated with the memory array having metal digit lines and a metal shield to the metal digit lines. The stack can include, but is not limited to, a silicon/silicon germanium/silicon (Si/SiGe/Si) regions. The stack is an “engineered substrate” that provides a set of platforms formed for processing. A platform for processing can be referred to as a substrate since particular processing can be conducted on or related to the specific platform.

Stack 100 represents regions formed in a series of procedures in the process flow, starting with a standard non-SOI substrate to create a new “substrate,” which can be processed. Stack 100 can include a starting substrate 108 on which a chemical mechanical polishing stop 107 can be positioned. A pillar platform 106 can be positioned on chemical mechanical polishing stop 107. A sacrificial silicon-on-insulator region 104 can be formed on pillar platform 106. A silicon-on-insulator platform 103 can be formed on sacrificial silicon-on-insulator region 104. A bonding oxide 102 can be positioned on silicon-on-insulator platform 103 and carrier wafer 101 can be positioned on bonding oxide 102. Stack 100 or a similar stack can be generated for a memory device in backside processing for a memory die followed by frontside processing for the memory die.

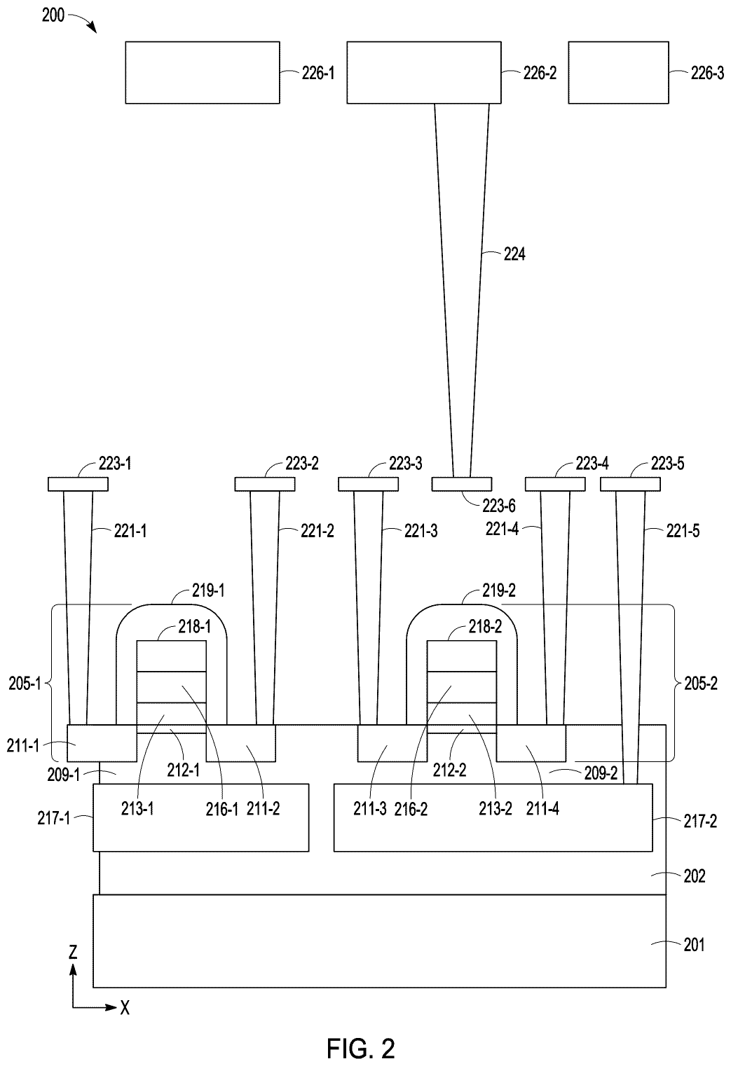

FIGS. 2-5 show embodiments of example different cross-sectional views of a memory device, where the views include views of a memory array region and views of a periphery to the memory array region. FIG. 2 shows a cross-sectional view of components of a periphery 200 to a memory array region. Periphery 200 includes a FDSOI transistor 205-1 and a FDSOI transistor 205-2. Though two FDSOI transistors are shown in FIG. 2, periphery 200 can have more or fewer than two FDSOI transistors. FDSOI transistor 205-1 and FDSOI transistor 205-2 can be structured as a FDSOI CMOS device.

FDSOI transistor 205-1 can be structured with a channel structure 212-1 between source/drain 211-1 and source/drain 211-2. A dielectric tunnel region 213-1 is positioned over channel structure 212-1 and a gate 216-1 is positioned on dielectric tunnel region 213-1. Dielectric tunnel region 213-1, which is a gate dielectric, can include one or more of silicon oxide, a high-k dielectric, or other dielectric. Herein, a high-k dielectric is a material that has a dielectric constant greater than the dielectric constant of silicon dioxide (3.9). An additional dielectric region 218-1 can be positioned on gate 216-1. A dielectric spacer 219-1 can be positioned about FDSOI transistor 205-1. A vertical conductive contact 221-1 couples source/drain 211-1 to a conductive landing pad 223-1 at a zeroth metal level (M0). A vertical conductive contact 221-2 couples source/drain 211-2 to a conductive landing pad 223-2 at M0.

FDSOI transistor 205-2 can be structured with a channel structure 212-2 between source/drain 211-3 and source/drain 211-4. A dielectric tunnel region 213-2 is positioned over channel structure 212-2 and a gate 216-2 is positioned on dielectric tunnel region 213-2. An additional dielectric region 218-2 can be positioned on gate 216-2. A dielectric spacer 219-2 is positioned about FDSOI transistor 205-2. A vertical conductive contact 221-3 couples source/drain 211-3 to a conductive landing pad 223-3, which can be at M0. A vertical conductive contact 221-4 couples source/drain 211-4 to a conductive landing pad 223-2 at M0. A vertical contact pillar 224 can couple a conductive landing pad 223-6 at M0 to a conductive landing pad 226-2 at a higher metallization level M1, which can include other conductive landing pads such as, but not limited to, landing pads 226-1 and 226-3. Conductive landing pads 223-1, 223-2, 223-3, 223-4, 223-5, and 223-6 can be structured as part of a common landing pattern (CLP) at M0, which can include significantly more landing pads. Landing pads at M1 can be in a CLP different from the CLP at M0.

Periphery 200 can include a conductive body plate 217-1 below FDSOI transistor 205-1 and separated from FDSOI transistor 205-1 by a buried dielectric 209-1. A conductive body plate 217-2 can be positioned below FDSOI transistor 205-2 and separated from FDSOI transistor 205-2 by a buried dielectric 209-2. Conductive body plates 217-1 and 217-2 can be metal body plates. Conductive body plates 217-1 and 217-2 can be separated by a dielectric or can be structured as a single conductive body plate. One or more of buried dielectric 209-1 and buried dielectric 209-2 can be a buried oxide. The thickness of buried dielectric 209-1 can be equal to thickness of buried dielectric 209-1. The thickness of a given buried dielectric can be measured as the distance between the conductive body plate and a source/drain area of the FDSOI transistor that the given buried dielectric separates. Buried dielectric 209-1 and buried dielectric 209-2 can be structured as a single buried dielectric.

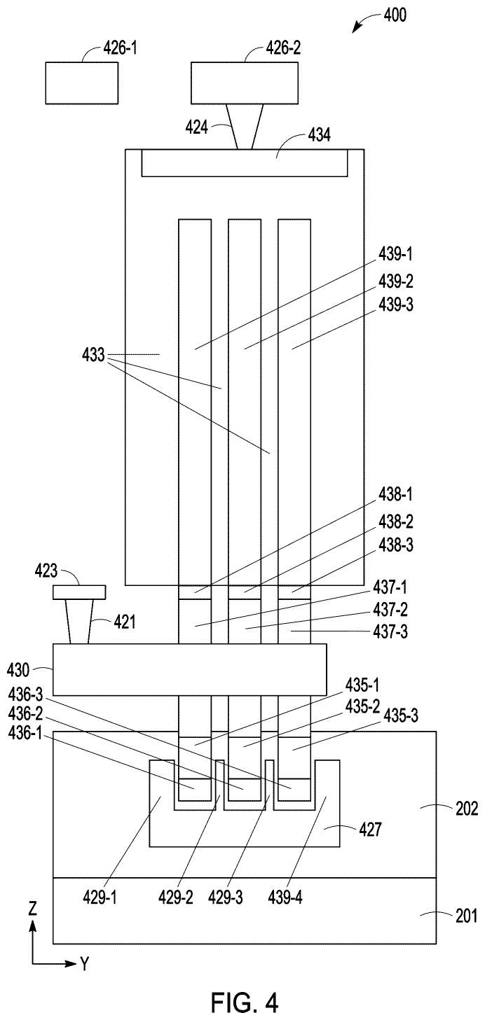

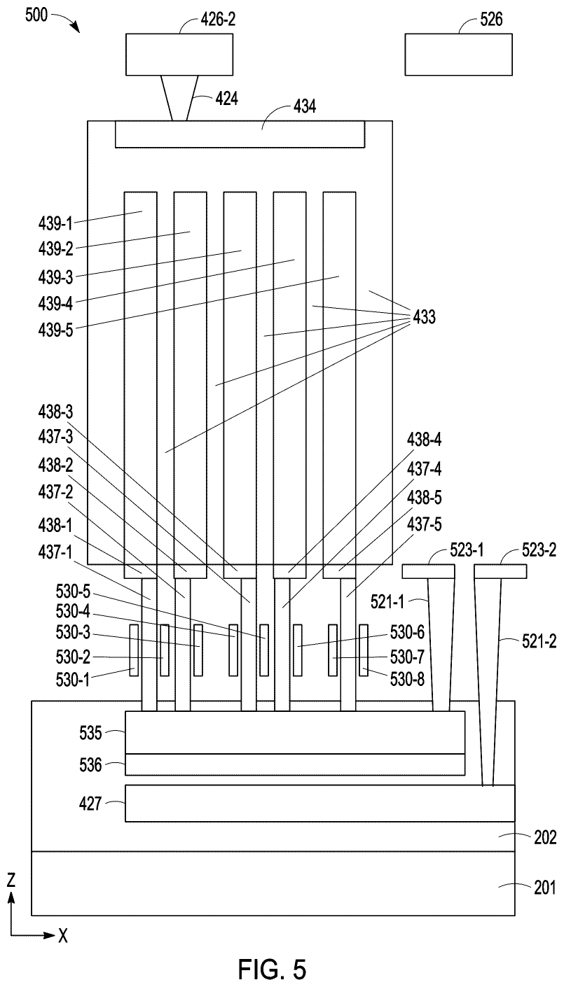

Conductive body plates 217-1 and 217-2 are separated from a carrier 201 by a bonding oxide 202. Carrier 201 and bonding oxide 202 are common to a memory array region to which periphery 200 is its periphery. Views of such memory array region are shown in FIGS. 4 and 5. Periphery 200 does not show all components of a periphery to a memory array region, but illustrates structures of FDSOI transistors in such periphery, in accordance with various embodiments for a memory device. The memory device can be a DRAM device.

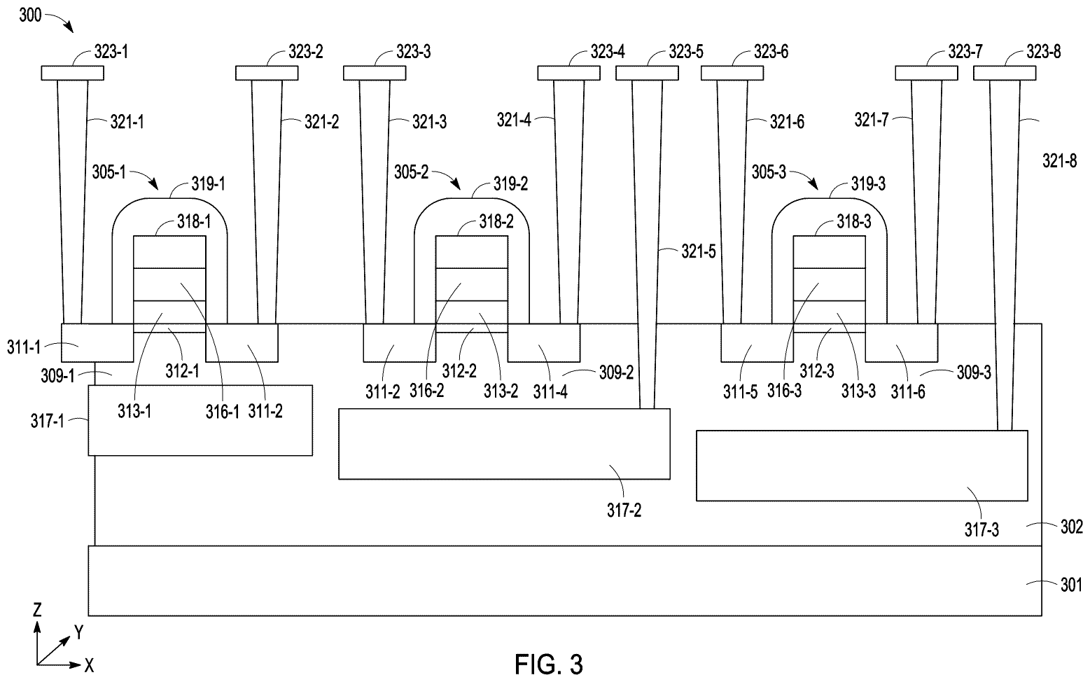

FIG. 3 shows a cross-sectional view of components of a periphery 300 to a memory array region. Periphery 300 includes a FDSOI transistor 305-1, a FDSOI transistor 305-2, and a FDSOI transistor 305-3. Although three FDSOI transistors are shown in FIG. 3, periphery 300 can have more than three FDSOI transistors.

FDSOI transistor 305-1 can be structured with a channel structure 312-1 between source/drain 311-1 and source/drain 311-2. A dielectric tunnel region 313-1 is positioned over channel structure 312-1 and a gate 316-1 is positioned on dielectric tunnel region 313-1. An additional dielectric region 318-1 can be positioned on gate 316-1. A dielectric spacer 319-1 can be positioned about FDSOI transistor 305-1. A vertical conductive contact 321-1 couples source/drain 311-1 to a conductive landing pad 323-1 at M0. A vertical conductive contact 321-2 couples source/drain 311-2 to a conductive landing pad 323-2 at M0.

FDSOI transistor 305-2 can be structured with a channel structure 312-2 between source/drain 311-3 and source/drain 311-4. A dielectric tunnel region 313-2 is positioned over channel structure 312-2 and a gate 316-2 is positioned on dielectric tunnel region 313-2. An additional dielectric region 318-2 can be positioned on gate 316-2. A dielectric spacer 319-2 can be positioned about FDSOI transistor 305-2. A vertical conductive contact 321-3 couples source/drain 311-3 to a conductive landing pad 323-3, which can be at M0. A vertical conductive contact 321-4 couples source/drain 311-4 to a conductive landing pad 323-4 at M0.

FDSOI transistor 305-3 can be structured with a channel structure 312-3 between source/drain 311-5 and source/drain 311-6. A dielectric tunnel region 313-3 is positioned over channel structure 312-3 and a gate 316-3 is positioned on dielectric tunnel region 313-3. An additional dielectric region 318-3 can be positioned on gate 316-3. A dielectric spacer 319-3 can be positioned about FDSOI transistor 305-3. A vertical conductive contact 321-6 couples source/drain 311-5 to a conductive landing pad 323-6, which can be at M0. A vertical conductive contact 321-7 couples source/drain 311-6 to a conductive landing pad 323-7 at M0.

Periphery 300 can include a conductive body plate 317-1 below FDSOI transistor 305-1 and separated from FDSOI transistor 305-1 by a buried dielectric 309-1. A conductive body plate 317-2 can be positioned below FDSOI transistor 305-2 and separated from FDSOI transistor 305-2 by a buried dielectric 309-2. A conductive body plate 317-3 can be positioned below FDSOI transistor 305-3 and separated from FDSOI transistor 305-3 by a buried dielectric 309-3. Conductive body plates 317-1, 317-2, and 317-3 can be metal body plates. Conductive body plates 317-1, 317-2, and 317-3 can be separated from each other by dielectric regions. One or more of buried dielectric 309-1, buried dielectric 309-2 and buried dielectric 309-3 can be a buried oxide. The thickness of buried dielectric 309-1 can be different from the thickness of buried dielectric 309-2 and different from the thickness of buried dielectric 309-3. The thickness of buried dielectric 309-2 can be different from the thickness of buried dielectric 309-1 and different from the thickness of buried dielectric 309-3.

Conductive body plate 317-2 can be coupled to conductive landing pad 323-5 at M0 via vertical conductive contact 321-5. Conductive body plate 317-3 can be coupled to conductive landing pad 323-8 at M0 via vertical conductive contact 321-8. Conductive body plate 317-1, conductive body plate 317-2, and conductive body plate 317-2 are separated from a carrier 301 by a bonding oxide 302. Carrier 301 and bonding oxide 302 are common to a memory array region to which periphery 300 is its periphery. Periphery 300 can be a variation of periphery 200 of FIG. 2. Materials compostions used in periphery 200 can be implemented in periphery 300. Periphery 300 does not show all components of a periphery to a memory array region, but illustrates structures of FDSOI transistors in such periphery, in accordance with various embodiments for a memory device. The memory device can be a DRAM device.

FIG. 4 shows a cross-sectional view 400 of components of a memory array region adjacent periphery 200 of FIG. 2. View 400 does not show all components of a memory array region that can be adjacent periphery 200. The memory array region can be a memory array region of a DRAM device. View 400 is along an access line 430, for example a word line. In this structure, access line 430 is in a direction that is orthogonal to the direction of digit lines 435-1, 435-2, and 435-3. Digit lines can be bit lines. Access line 430 is coupled to a conductive landing pad 423 via a vertical conductive contact 421. Conductive landing pad 423 can be at M0.

Conductive shield lines 429-1, 429-2, 429-3, and 429-4 are positioned between digit lines 435-1, 435-2, and 435-3. Conductive shield line 429-1 shields digit line 435-1 from conductive areas to the left of digit line 435-1 in view 400. Conductive shield line 429-2 shields digit line 435-2 from digit line 435-1. Conductive shield line 429-3 shields digit line 435-3 from digit line 435-2. Conductive shield line 429-4 shields digit line 435-3 from conductive areas to the right of digit line 435-3 in view 400. Conductive shield lines 429-1, 429-2, 429-3, and 429-4 are coupled to a digit shield 427. Digit shield 427 is a conductive shield. Digit lines 435-1, 435-2, and 435-3 are separated from digit shield 427 by dielectric regions 436-1, 436-2, and 436-3, respectively. Digit shield 427 is separated from carrier 201 by bonding oxide 202, where carrier 201 and bonding oxide 202 are common to periphery 200 of FIG. 2. Digit lines 435-1, 435-2, and 435-3 are coupled to access transistors represented by 437-1 and 438-1, 437-2 and 438-2, and 437-3 and 438-3, respectively. Access transistors represented by 437-1 and 438-1, 437-2 and 438-2, and 437-3 and 438-3 are coupled to bottom electrodes 439-1, 439-2, and 439-3, respectively, of capacitors of memory cells of the memory array region. Bottom electrodes 439-1, 439-2, and 439-3 are separated from a top electrode plate 434 by a dielectric 433. Top electrode plate 434 is coupled to a conductive landing pad 426-2 by a vertical conductive contact 424 at M1, where M1 can include conductive landing pad 426-1 among other conductive landing pads.

FIG. 5 shows a cross-sectional view 500 of components of a memory array region adjacent periphery 200 of FIG. 2. View 500 does not show all components of a memory array region that can be adjacent periphery 200. The memory array region can be a memory array region of a DRAM device. View 500 is along a digit line 535. In this structure, digit line 535 is in a direction that is orthogonal to the direction of access lines 530-1, 530-2, 530-3, 530-4, 530-5, 530-6, 530-7, and 530-8. Digit line 535 is coupled to a conductive landing pad 523-1 via a vertical conductive contact 521-1. Conductive landing pad 523-1 can be at M0. Digit shield 427 is below digit line 535 and dielectric 536 is coupled to digit line 535. Digit shield 427 is separated from carrier 201 by bonding oxide 202, where carrier 201 and bonding oxide 202 are common to periphery 200 of FIG. 2.

Digit line 535 is coupled to access transistors represented by 437-1 and 438-1, 437-2 and 438-2, 437-3 and 438-3, 437-4 and 438-4, and 437-4 and 438-5. Access transistors represented by 437-1 and 438-1, 437-2 and 438-2, 437-3 and 438-3, 437-4 and 438-4, and 437-4 and 438-5 are coupled to bottom electrodes 439-1, 439-2, 439-3, 439-4, and 439-5, respectively, of capacitors of memory cells of the memory array region. Bottom electrodes 439-1, 439-2, 439-3, 439-4, and 439-5 are separated from top electrode plate 434 by dielectric 433. Top electrode plate 434 is coupled to a conductive landing pad 426-2 at M1 by a vertical conductive contact 424, where M1 can include conductive landing pad 526 among other conductive landing pads.

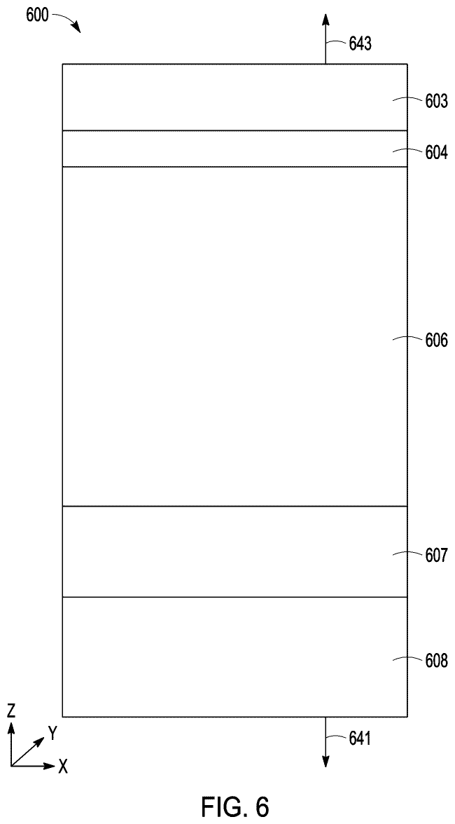

FIG. 6 shows an embodiment of an example substrate structure 600 that is an engineered substrate that can be used to fabricate a memory device having the memory array regions and peripheries of or similar to FIGS. 2-5. Structure 600 can be structured with silicon (Si) and silicon germanium (SiGe) to make complex substrate features for co-integrating the memory array region and periphery. Structure 600 can include a Si starting wafer 608 on which an epitaxial SiGe is grown to be a sacrificial region 607 for chemical mechanical polishing (CMP). Epitaxial Si is formed on sacrificial region 607 to provide a pillar substrate 606 for a 4F² configuration of memory cells. A sacrificial region 604 of epitaxial SiGe is formed on pillar substrate 606 for SOI singulation. A SOI substrate 603 of epitaxial Si is formed on sacrificial region 604, where SOI substrate 603 can be implemented for CMOS formation. Direction 643 can be used for digit line processing and direction 641 can be used for capacitors of a DRAM device.

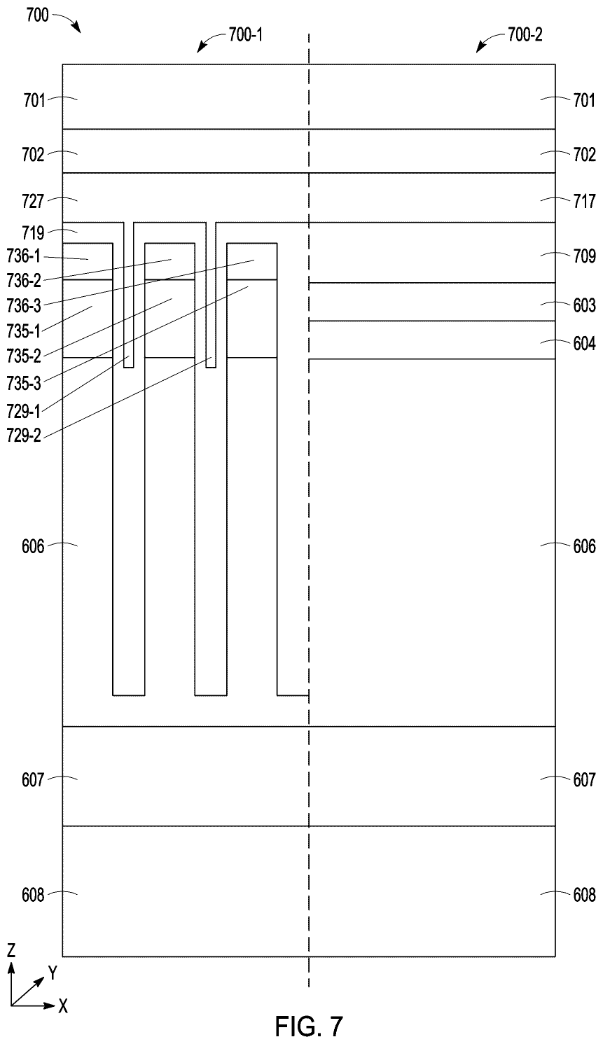

FIGS. 7-10 illustrate embodiments of an example process flow of integrated periphery and memory array region for a memory dic, in which the periphery includes one or more FDSOI transistors. FIG. 7 illustrates a cross-sectional view of a structure 700 having a memory array region 700-1 and a periphery 700-2 to memory array region 700-1. A dotted line represents separation of memory array region 700-1 and periphery 700-2. This cross-sectional view illustrates components being generated from backside processing of substrate structure 600. In the backside processing of periphery 700-2, a buried oxide 709 has been formed on SOI substrate 603. Optionally, patterning can be performed for CMOS devices and pattering of a SOI plate as a body plate 717. In the backside processing of memory array region 700-1, DL metal lines 735-1, 735-2, and 735-3 have been deposited and patterned, with DL metal lines 735-1, 735-2, and 735-3 separated from each other by a dielectric 719. Dielectric capping regions 736-1, 736-2, and 736-3 have been deposited to DL metal lines 735-1, 735-2, and 735-3, respectively. Digit shield line 729-1 has been formed between DL metal lines 735-1 and 735-2, and digit shield line 729-2 has been formed between DL metal lines 735-2 and 735-3. A digit shield 727 has been formed with DL metal lines 735-1, 735-2, and 735-3 having been formed extending from digit shield 727.

Backside processing can include, but is not limited to, forming digit shield 727 in memory array region 700-1 and forming body plate 717 in the same time period. Body plate 717 and digit shield 727 can be formed as conductive regions such as, but not limited to, metal regions. The conductive material can be the same in body plate 717 and digit shield 727. A bonding oxide 702 has been formed on both memory array region 700-1 and periphery 700-2. A carrier wafer 701 has been positioned on bonding oxide 702 as common components in both memory array region 700-1 and periphery 700-2.

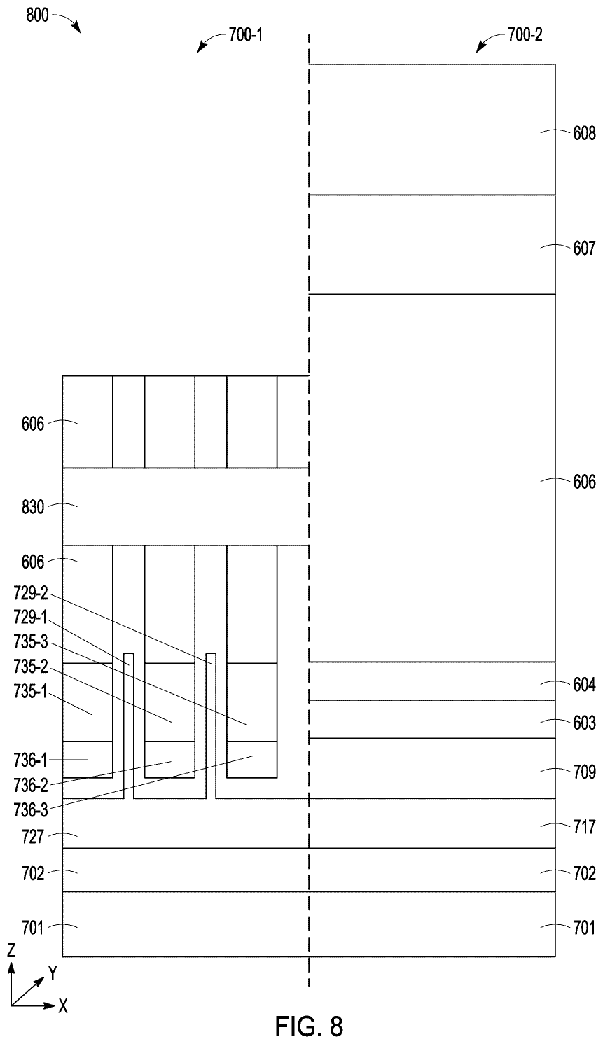

FIG. 8 illustrates a cross-sectional view of a structure 800 having memory array region 700-1 and periphery 700-2 to memory array region 700-1, after further processing of structure 700 of FIG. 7. Structure 700 has been inverted to perform frontside processing. In memory array region 700-1 of struture 800, Si starting wafer 608 has been polished down, removing material stopping at SiGe of sacrificial region 607 that remains in periphery 700-2. SiGe of sacrificial region 607 has been removed in memory array region 700-1. The removal can be conducted via a selective etching in memory array region 700-1, with SiGe of sacrificial region 607 remaining in periphery 700-2. The selective etching of SiGe can be performed by wet etching. Pillar substrate 606 has been patterned for an array pillar. An access line 830 has been formed. FIG. 8 is a cross-sectional view along the direction of access line 830 and, as a result, only access line 830 of the module of access lines for the memory array of memory cells is shown.

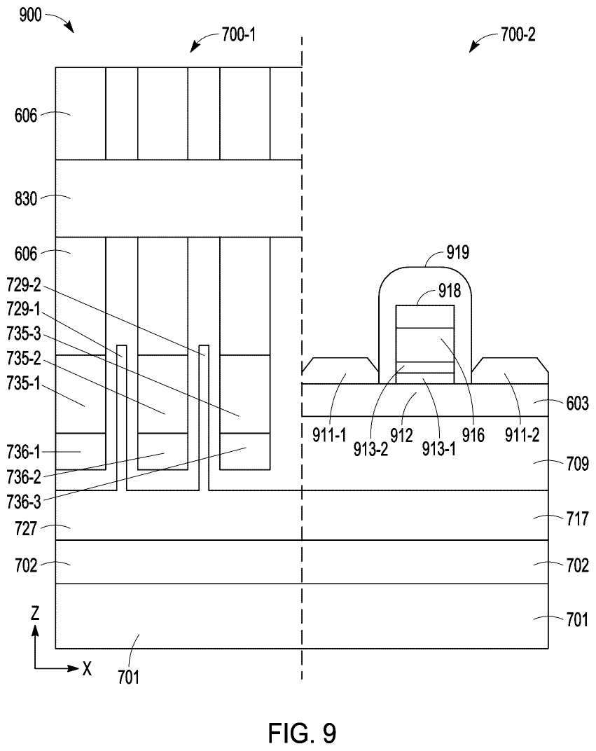

FIG. 9 illustrates a cross-sectional view of a structure 900 having memory array region 700-1 and periphery 700-2 to memory array region 700-1, after further frontside processing of structure 800 of FIG. 8. In periphery 700-2, SiGe sacrificial region 604, pillar substrate 606, SiGe of sacrificial region 607, and Si starting wafer 608 have been removed prior to forming transistors for a CMOS module. The CMOS module can include multiple CMOS devices in periphery 700-2 structured with FDSOI transistors. FIG. 9 shows one FDSOI transistor that has been structured as part of such a CMOS device formed in SOI substrate 603. The FDSOI transistor has been structured with a channel structure 912 between source/drain 911-1 and source/drain 911-2. Channel structure 912 can have the composition of SOI substrate 603, which can be, but is not limited to, epitaxial Si. A gate dielectric has been positioned over channel structure 912 and a gate 916 has been positioned on the gate dielectric. The gate dielectric can include gate dielectric 913-1 and gate dielectric 913-2. The materials of gate dielectric 913-1 and gate dielectric 913-2 can be different dielectrics. For example, the gate dielectric can be a combination of dielectric oxide and high-K dielectric materials. A high-K dielectric is a dielectric with a dielectric constant greater than the dielectric constant of silicon dioxide. Variations of a gate dielectric can include one or more dielectric layers having one or more dielectric compositions. Gate 916 can be a conductor formed of a metal, polysilicon, a combination of a metal and polysilicon, or other appropriate conductive material. An additional dielectric region 918 has been positioned on gate 916. Additional dielectric region 918 can be provided as an insulator on top of gate 916 and can include a dielectric nitride or similar dielectric material. A dielectric spacer 919 has been positioned about the FDSOI transistor. Dielectric spacer 919 can be structured as a spacer on both sides of gate 916 and can include a dielectric nitride, a dielectric oxide, a combination of a dielectric nitride and a dielectric oxide, or similar material.

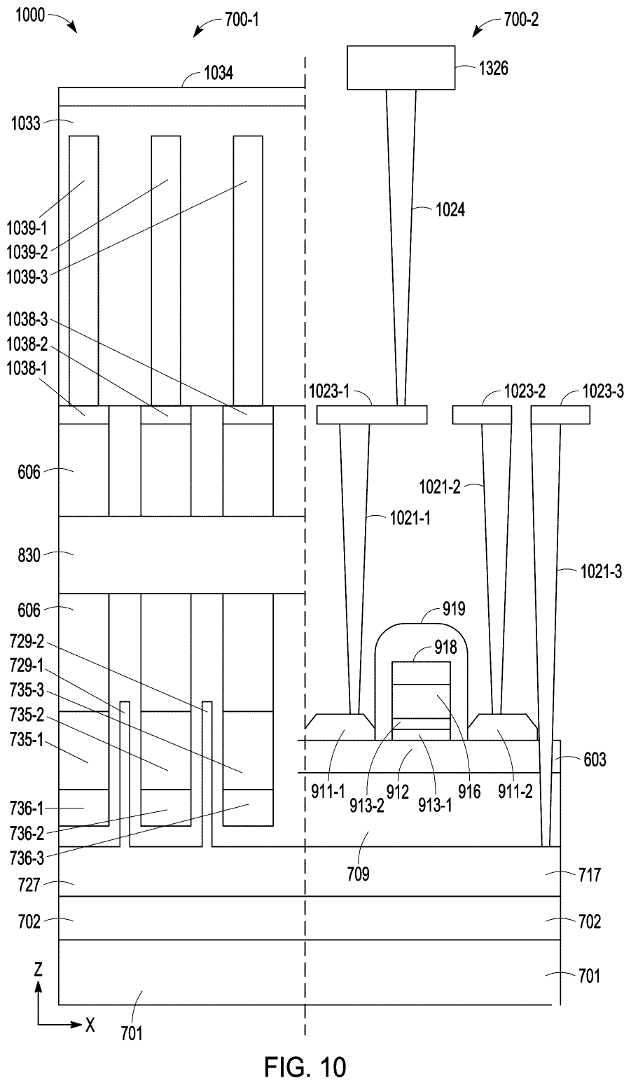

FIG. 10 illustrates a cross-sectional view of a structure 1000 having memory array region 700-1 and a periphery 700-2 to memory array region 700-1, after further frontside processing of structure 900 of FIG. 9. In memory array region 700-1, metallizations have been performed, in which contacts 1038-1, 1038-2, and 1038-3 have been formed for capacitors to access transistors, where the transistors are coupled to DL metal lines 735-1, 735-2, and 735-3. Access line 830 is coupled to the access transistors represented by pillar substrate 606 and contacts 1038-1, 1038-2, and 1038-3, respectively. Bottom electrodes 1039-1, 1039-2, and 1039-3 have been formed, separated from a top electrode plate 1034. Bottom electrodes 1039-1, 1039-2, and 1039-3 have been formed with a capacitor dielectric 1033.

In periphery 700-2, metallizations have been performed in which conductive landing pads 1023-1, 1023-2, and 1023-3 have been formed at M0. A vertical conductive contact 1021-1 has been formed, coupling source/drain 911-1 to a conductive landing pad 1023-1 at M0. A vertical conductive contact 1021-2 has been formed, coupling source/drain 911-2 to a conductive landing pad 1023-2 at M0. A conductive landing pad 1023-3 has been formed and coupled to body plate 717 by a vertical conductive contact 1021-3. A conductive landing pad 1026 has been formed at M1 and coupled to conductive landing pad 1023-1 by a vertical conductive contact 1024.

FIGS. 6-10 show formation of components of a DRAM device using a backside and frontside processing flow. Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Etching procedures can include, but are not limited to, wet etching, dry etching, and atomic layer etching deposition, among others. Formation of other components of such a DRAM device are not shown to focus on formation FDSOI transistors in a periphery to the memory array region of the DRAM device. Formation of additional components, such as, but not limited to, a conductive body plate and a conductive digit shield, associated an architecture of a DRAM device having FDSOI transistors in the periphery, in accordance with various embodiments, have been shown.

Forming FDSOI transistors in the periphery to the memory array of a memory device can enable CMOS device scaling in the periphery with performance comparable to that of fin field-effect transistors (FinFETs) in a memory device periphery. Further, SiGe processing for such FDSOI transistors can enable clean surfaces for CMOS oxide interfaces associated with CMOS devices in the periphery. In addition, a 4F² memory array configuration for a memory device, such as a DRAM device, can be realized with metal DL lines and a metal DL shield.

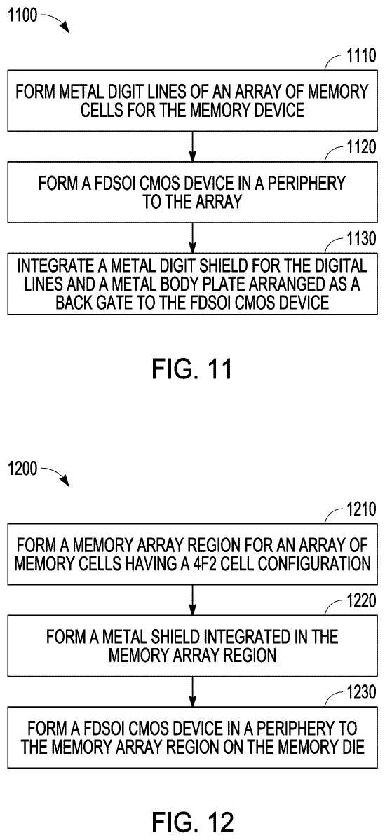

FIG. 11 is a flow diagram of features of an embodiment of an example method 1100 of forming an memory device. At 1110, metal digit lines of an array of memory cells for the memory device are formed. At 1120, a FDSOI CMOS device is formed in a periphery to the array. At 1130, a metal digit shield for the metal digit lines and a metal body plate arranged as a back gate to the FDSOI CMOS device are integrated. The array of memory cells can be formed having, but not limited to, a 4F² cell configuration.

Variations of method 1100 or methods similar to method 1100 can include a number of different embodiments that may be combined depending on the application of such methods and/or the architecture of systems including a memory device in which such methods are implemented. Such methods can include forming the metal digit shield and the metal body plate in backside processing and forming the array in frontside processing. Variations can include forming metal shield lines extending from the metal digit shield between adjacent digit lines.

Variations of method 1100 or methods similar to method 1100 can include, prior to backside processing, forming a bonding oxide on a carrier wafer and forming a silicon-on-insulator platform on the bonding oxide. A sacrificial silicon-on-insulator region can be formed on the silicon-on-insulator platform and a pillar platform can be formed on the sacrificial silicon-on-insulator region. A chemical mechanical polishing stop can be formed on the pillar platform and a starting substrate can be formed on the chemical mechanical polishing stop. The silicon-on-insulator substrate can have a thickness in a range of about ten to about twenty nanometers. Variations can include forming a sacrificial silicon germanium region to provide an oxide interface for the FDSOI CMOS device.

In various embodiments, a memory device can comprise a memory array region on a memory dic, the memory array region having an array of memory cells, and a periphery to the memory array region on the memory die. The periphery can include a FDSOI CMOS device. The memory device can include a metal shield integrated in the memory array region, where the metal shield is a shield to digit lines of the array. The memory device can also include a metal body plate arranged as a back gate to the FDSOI CMOS device.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the digit lines being metal digit lines. The memory array region can include metal shield lines between adjacent digit lines in the memory array region. The metal shield lines can extend from the metal shield in the memory array region.

Variations of such a memory device and its features can include channels of the FDSOI CMOS device being separated from the metal body plate in the periphery by a buried oxide. The metal body plate can include a first body plate separated from a second body plate by an insulating dielectric region. The metal body plate and the metal shield can have a common composition. Variations of such a memory device and its features can include the array of memory cells having a 4F² cell configuration.

FIG. 12 is a flow diagram of features of an embodiment of an example method 1200 of forming a DRAM. At 1210, a memory array region is formed on a memory die, where the memory array region is arranged for an array of memory cells having a 4F² cell configuration. At 1220, a metal shield is formed integrated in the memory array region, where the metal shield is a shield to digit lines of the array. At 1230, a FDSOI CMOS device is formed in a periphery to the memory array region on the memory die.

Variations of method 1200 or methods similar to method 1200 can include a number of different embodiments that may be combined depending on the application of such methods and/or the architecture of systems including a memory device in which such methods are implemented. Such methods can include forming metal shield lines extending from the metal digit shield between adjacent digit lines. Variations can include forming a sacrificial silicon germanium region to provide an oxide interface for the FDSOI CMOS device.

Variations of method 1200 or methods similar to method 1200 can include forming a metal body plate in the periphery while forming metal material for the metal shield in the memory array region and arranging the metal body plate as a back gate to the FDSOI CMOS device. The metal body plate arrangement can include a first back gate to a first FDSOI transistor of the FDSOI CMOS device and a second back gate to a second FDSOI transistor of the FDSOI CMOS device, where the first back gate is separated from the second back gate by an insulating region. Variations can include forming FDSOI transistors in the periphery with metal back gates separated from channels of the FDSOI transistors by dielectric insulating regions, where each dielectric insulating region has a different thickness than the other dielectric insulating regions. For each of these dielectric insulating regions, the thickness can be measured by the distance from the metal back gate to an active region of the respective FDSOI transistors.

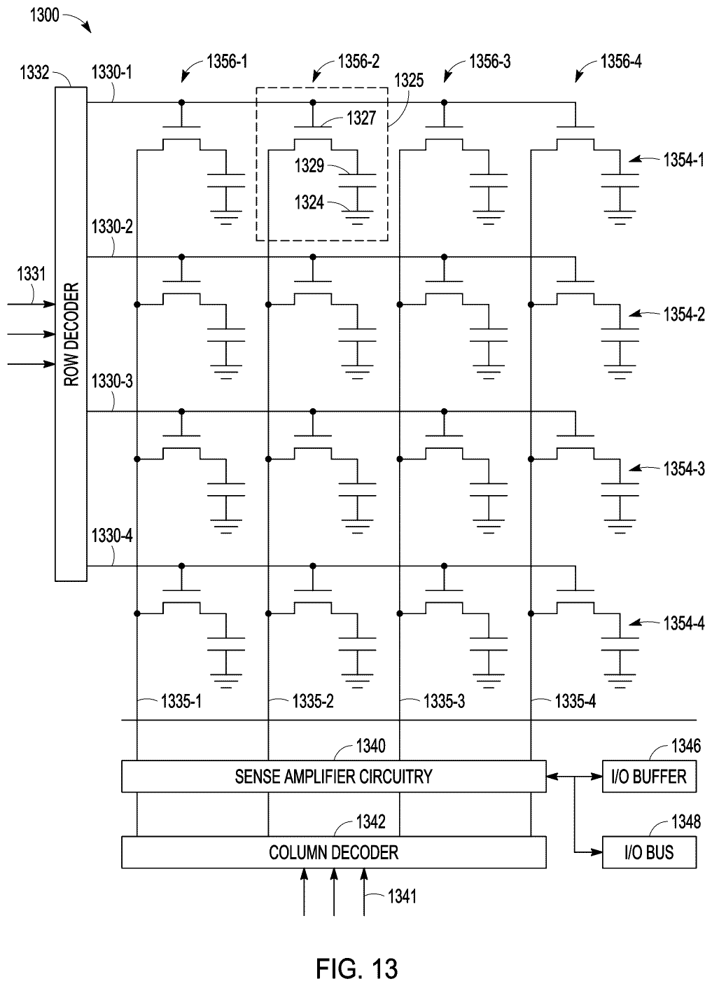

FIG. 13 is a schematic of an embodiment of an example DRAM device 1300 that can include an architecture having a memory array region and periphery circuits to the memory array, in which the periphery circuits can have FDSOI transistors as discussed herein with respect to FIGS. 1-12. DRAM device 1300 can include an array of memory cells 1325 (only one being labeled in FIG. 13 for case of presentation) arranged in rows 1354-1, 1354-2, 1354-3, and 1354-4 and columns 1356-1, 1356-2, 1356-3, and 1356-4. For simplicity and case of discussion, the array is shown in only two dimensions, but the array can be extended into the third dimension. Further, while only four rows 1354-1, 1354-2, 1354-3, and 1354-4 and four columns 1356-1, 1356-2, 1356-3, and 1356-4 of four memory cells are illustrated, DRAM devices, like DRAM device 1300, can have significantly more memory cells 1325 (e.g., tens, hundreds, or thousands of memory cells) per row or per column.

Each memory cell 1325 can include a single transistor 1327 and a single capacitor 1329, which is commonly referred to as a 1T1C (one-transistor-one capacitor cell). One plate of capacitor 1329, which can be termed the “node plate,” is connected to the drain terminal of transistor 1327, whereas the other plate of the capacitor 1329 is connected to ground 1324 or other reference node. Each capacitor 1329 within the array of 1T1C memory cells 1325 typically serves to store one bit of data, and the respective transistor 1327 serves as an access device to write to or read from storage capacitor 1329.

The transistor gate terminals within each row of rows 1354-1, 1354-2, 1354-3, and 1354-4 are portions of respective access lines 1330-1, 1330-2, 1330-3, and 1330-4 (alternatively referred to as “word lines”), and the transistor source terminals within each of columns 1356-1, 1356-2, 1356-3, and 1356-4 are electrically connected to respective digit lines 1335-1, 1335-2, 1335-3, and 1335-4 (alternatively referred to as “bit lines”). A row decoder 1332 can selectively drive the individual access lines 1330-1, 1330-2, 1330-3, and 1330-4, responsive to row address signals 1331 input to row decoder 1332. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier (SA) circuitry 1340, which can transfer bit values between the memory cells 1325 of the selected row of the rows 1354-1, 1354-2, 1354-3, and 1354-4 and input/output buffers 1346 (for write/read operations) or external input/output data buses 1348. SA circuitry 1340 can include one or more FDSOI transistors, as taught herein. A set of the one or more FDSOI transistors can include FDSOI transistors structured as one or more CMOS devices.

A column decoder 1342 responsive to column address signals 1341 can select which of the memory cells 1325 within the selected row is read out or written to. Alternatively, for read operations, the storage capacitors 1329 within the selected row can be read out simultaneously and latched, and the column decoder 1342 can then select which latch bits to connect to the output data bus 1348. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1300 can be implemented as an integrated circuit within a package that includes pins for receiving supply voltages (e.g., to provide the source and gate voltages for the transistors 1327) and signals (including data, address, and control signals). FIG. 13 depicts DRAM device 1300 in simplified form to illustrate basic structural components, omitting many details of the memory cells 1325 and associated access lines 1330-1, 1330-2, 1330-3, and 1330-4 and digit lines 1335-1, 1335-2, 1335-3, and 1335-4 as well as the peripheral circuitry. For example, in addition to the row decoder 1332 and column decoder 1342, SA circuitry 1340, and buffers 1346, DRAM device 1300 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1354-1, 1354-2, 1354-3, and 1354-4 and columns 1356-1, 1356-2, 1356-3, and 1356-4 of memory cells 1325 can be arranged along a single horizontal plane (i.e., a plane parallel to the layers) of the semiconductor substrate, e.g., in a rectangular lattice with mutually perpendicular horizontal access lines 1330-1, 1330-2, 1330-3, and 1330-4 and digit lines 1335-1, 1335-2, 1335-3, and 1335-4. In 3D DRAM arrays, the memory cells 1325 can be arranged in a 3D lattice that encompasses multiple vertically stacked horizontal planes corresponding to multiple device tiers of a multi-tier substrate assembly, with each device tier including multiple parallel rows of memory cells 1325 whose transistor gate terminals are connected by horizontal access lines such as access lines 1330-1, 1330-2, 1330-3, and 1330-4. (A “device tier,” as used herein, can include multiple layers (or levels) of materials, but forms the components of memory devices of a single horizontal tier of memory cells.) Digit lines 1335-1, 1335-2, 1335-3, and 1335-4 extend vertically through all or at least a vertical portion of the multi-tier structure, and each of the digit lines 1335-1, 1335-2, 1335-3, and 1335-4 connects to the transistor source terminals of respective vertical columns 1356-1, 1356-2, 1356-3, and 1356-4 of associated memory cells 1325 at the multiple device tiers. This 3D configuration of memory cells enables further increases in bit density compared with 2D arrays.

Although FIG. 13 provides an example of DRAM 1300 that can include FDSOI transistors in the periphery to a memory array region, as discussed with respect to FIGS. 1-12, other ICs can implement similar FDSOI transistors that can be used in a variety of electronic devices. Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include FDSOI transistor devices in a periphery to a memory array region within the electronic devices.

The following examples are example embodiments of devices and methods, in accordance with the teachings herein.

An example memory device 1 can comprise a memory array region on a memory die, the memory array region having an array of memory cells; a periphery to the memory array region on the memory die, the periphery including a FDSOI CMOS device; a metal shield integrated in the memory array region, the metal shield being a shield to digit lines of the array; and a metal body plate arranged as a back gate to the FDSOI CMOS device.

An example memory device 2 can include features of example memory device 1 and can include the digit lines being metal digit lines.

An example memory device 3 can include features of any of the preceding example memory devices and can include the memory array region having metal shield lines between adjacent digit lines in the memory array region.

An example memory device 4 can include features of example memory device 4 and any of the preceding example memory devices and can include the metal shield lines extending vertically from the metal shield in the memory array region.

An example memory device 5 can include features of any of the preceding example memory devices and can include channels of the FDSOI CMOS device being separated from the metal body plate in the periphery by a buried oxide.

An example memory device 6 can include features of example memory device 5 and any of the preceding example memory devices and can include the metal body plate including a first body plate separated from a second body plate by an insulating dielectric region.

An example memory device 7 can include features of example memory device 5 and any of the preceding example memory devices and can include the metal body plate and the metal shield having a common composition.

An example memory device 8 can include features of example memory device 5 and any of the preceding example memory devices and can include the array of memory cells having a 4F² cell configuration.

In an example memory device 9, any of the memory devices of example memory devices 1 to 8 may include memory devices incorporated into an electronic apparatus further comprising a host processor and a communication bus extending between the host processor and the memory device. In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below example methods 1 to 11 of forming a memory device or example methods 1 to 9 of forming a DRAM.

An example method 1 of forming a memory device can comprise forming metal digit lines of an array of memory cells for the memory device; forming a FDSOI CMOS device in a periphery to the array; and integrating a metal digit shield for the metal digit lines and a metal body plate arranged as a back gate to the FDSOI CMOS device.

An example method 2 of forming a memory device can include features of example method 1 of forming a memory device and can include forming the metal digit shield and the metal body plate in backside processing and forming the array in frontside processing.

An example method 3 of forming a memory device can include features of any of the preceding example methods of forming a memory device and can include forming metal shield lines extending vertically from the metal digit shield between adjacent digit lines.

An example method 4 of forming a memory device can include features of any of the preceding example methods of forming a memory device and can include forming a sacrificial silicon germanium region to provide an oxide interface for the FDSOI CMOS device.

An example method 5 of forming a memory device can include features of any of the preceding example methods of forming a memory device and can include forming the array of memory cells having a 4F² cell configuration.

An example method 6 of forming a memory device can include features of any of the preceding example methods of forming a memory device and can include forming a chemical mechanical polishing stop on a starting substrate; forming a pillar platform on the chemical mechanical polishing stop; forming a sacrificial silicon-on-insulator region on the pillar platform; forming a silicon-on-insulator platform on the sacrificial silicon-on-insulator region; forming a bonding oxide on the silicon-on-insulator platform; and forming a carrier wafer on the bonding oxide.

An example method 7 of forming a memory device can include features of example method 6 of forming a memory device and any of the preceding example methods of forming a memory device and can include the silicon-on-insulator platform having a thickness in a range of about ten to about twenty nanometers.

In an example method 8 of forming a memory device, any of the example methods 1 to 7 of forming a memory device may be performed in forming an electronic apparatus further comprising a host processor and a communication bus extending between the host processor and the memory device.

In an example method 9 of forming a memory device, any of the example methods 1 to 8 of forming a memory device may be modified to include operations set forth in any other of example methods 1 to 8 of forming a memory device.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include performing functions associated with any features of example memory devices 1 to 12.

An example method 1 of forming a DRAM can comprise forming a memory array region on a memory die, the memory array region arranged for an array of memory cells having a 4F² cell configuration; forming a metal shield integrated in the memory array region, the metal shield being a shield to digit lines of the array; and forming a FDSOI CMOS device in a periphery to the memory array region on the memory die.

An example method 2 of forming a DRAM can include features of example method 1 of forming a DRAM and can include forming metal shield lines extending vertically from the metal shield between adjacent digit lines.

An example method 3 of forming a DRAM can include features of any of the preceding example methods of forming a DRAM and can include forming a metal body plate in the periphery while forming metal material for the metal shield in the memory array region; and arranging the metal body plate as a back gate to the FDSOI CMOS device.

An example method 4 of forming a DRAM can include features of example method 3 of forming a DRAM and any of the preceding example methods of forming a DRAM and can include arranging the metal body plate to include arranging the metal body plate as a first back gate to a first FDSOI transistor and a second back gate to a second FDSOI transistor, the first back gate separated from the second back gate by an insulating region.

An example method 5 of forming a DRAM can include features of any of the preceding example methods of forming a DRAM and can include forming a sacrificial silicon germanium region to provide an oxide interface for the FDSOI CMOS device.

In an example method 6 of forming a DRAM, any of the example methods 1 to 5 of forming a DRAM may be performed in forming an electronic apparatus further comprising a host processor and a communication bus extending between the host processor and the DRAM.

In an example method 7 of forming a DRAM, any of the example methods 1 to 6 of forming a DRAM may be modified to include operations set forth in any other of example methods 1 to 6 of forming a DRAM.

In an example method 8 of forming a DRAM, any of the example methods 1 to 7 of forming a DRAM may be implemented at least in part through use of instructions stored as a physical state in one or more machine-readable storage devices.

An example method 9 of forming a DRAM can include features of any of the preceding example methods 1 to 8 of forming a DRAM and can include performing functions associated with any features of example DRAM 1 to 8.

An example machine-readable storage device storing instructions, that when executed by one or more processors, cause a machine to perform operations, can comprise instructions to perform functions associated with any features of example memory devices 1 to 12 or perform methods associated with any features of example methods 1 to 11 of forming a memory device or example methods 1 to 9 of forming a DRAM.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a memory array region on a memory die, the memory array region having an array of memory cells;
a periphery to the memory array region on the memory die, the periphery including a fully depleted silicon-on-insulator (FDSOI) complementary metal-oxide-semiconductor (CMOS) device;
a metal shield integrated in the memory array region, the metal shield being a shield to digit lines of the array; and
a metal body plate arranged as a back gate to the FDSOI CMOS device.

2. The memory device of claim 1, wherein the digit lines are metal digit lines.

3. The memory device of claim 1, wherein the memory array region includes metal shield lines between adjacent digit lines in the memory array region.

4. The memory device of claim 3, wherein the metal shield lines extend vertically from the metal shield in the memory array region.

5. The memory device of claim 1, wherein channels of the FDSOI CMOS device are separated from the metal body plate in the periphery by a buried oxide.

6. The memory device of claim 1, wherein the metal body plate includes a first body plate separated from a second body plate by an insulating dielectric region.

7. The memory device of claim 1, wherein the metal body plate and the metal shield have a common composition.

8. The memory device of claim 1, wherein the array of memory cells has a 4F² cell configuration.

9. A method of forming an memory device, the method comprising:
forming metal digit lines of an array of memory cells for the memory device;
forming a fully depleted silicon-on-insulator (FDSOI) complementary metal-oxide-semiconductor (CMOS) device in a periphery to the array; and
integrating a metal digit shield for the metal digit lines and a metal body plate arranged as a back gate to the FDSOI CMOS device.

10. The method of claim 9, wherein the method includes forming the metal digit shield and the metal body plate in backside processing and forming the array in frontside processing.

11. The method of claim 9, wherein the method includes forming metal shield lines extending vertically from the metal digit shield between adjacent digit lines.

12. The method of claim 9, wherein the method includes forming a sacrificial silicon germanium region to provide an oxide interface for the FDSOI CMOS device.

13. The method of claim 9, wherein the method includes forming the array of memory cells having a 4F² cell configuration.

14. The method of claim 9, wherein the method includes:
forming a chemical mechanical polishing stop on a starting substrate;
forming a pillar platform on the chemical mechanical polishing stop;
forming a sacrificial silicon-on-insulator region on the pillar platform;
forming a silicon-on-insulator platform on the sacrificial silicon-on-insulator region;
forming a bonding oxide on the silicon-on-insulator platform; and
forming a carrier wafer on the bonding oxide.

15. The method of claim 14, wherein the silicon-on-insulator platform has a thickness in a range of about ten to about twenty nanometers.

16. A method of forming a dynamic random-access memory, the method comprising:
forming a memory array region on a memory die, the memory array region arranged for an array of memory cells having a 4F² cell configuration;
forming a metal shield integrated in the memory array region, the metal shield being a shield to digit lines of the array; and
forming a fully depleted silicon-on-insulator (FDSOI) complementary metal-oxide-semiconductor (CMOS) device in a periphery to the memory array region on the memory die.

17. The method of claim 16, wherein the method includes forming metal shield lines extending vertically from the metal shield between adjacent digit lines.

18. The method of claim 16, wherein the method includes:
forming a metal body plate in the periphery while forming metal material for the metal shield in the memory array region; and
arranging the metal body plate as a back gate to the FDSOI CMOS device.

19. The method of claim 18, wherein arranging the metal body plate includes arranging the metal body plate as a first back gate to a first FDSOI transistor and a second back gate to a second FDSOI transistor, the first back gate separated from the second back gate by an insulating region.

20. The method of claim 16, wherein the method includes forming a sacrificial silicon germanium region to provide an oxide interface for the FDSOI CMOS device.
